(19) United States
(12) Patent Application Publication
(10) Pub. No.: US 2023/0217633 A1
(43) Pub. Date: Jul. 6, 2023

(54) CONTAINER DATA CENTER, EDGE DATA CENTER, AND WORKING METHOD

(71) Applicant: Alibaba (China) Co., Ltd., Hangzhou (CN)

(72) Inventor: Huahua REN, Beijing (CN)

(21) Appl. No.: 18/146,166

(22) Filed: Dec. 23, 2022

(30) Foreign Application Priority Data
Dec. 31, 2021 (CN) 202111666819.8

(51) Int. Cl. H05K 7/20; H05K 7/14

(52) U.S. Cl. CPC H05K 7/20836; H05K 7/1492; H05K 7/1497; H05K 7/2079; H05K 7/20236; H05K 7/20281

(57) ABSTRACT

A container data center is provided. The data center is provided in a shipping container, and the container data center includes a cooling system including a plurality of cooling devices for cooling the data center; a power supply and distribution system including a power supply circuit for supplying power to the data center; and a control system electrically connected to the cooling system and the power supply and distribution system; wherein the control system comprises a plurality of control devices, the plurality of control devices each configured to control a part of the cooling devices, and when a first part of the plurality of control devices cannot work, a working mode of a second part of the control devices is adjusted to control the plurality of the cooling devices.

### CROSS-REFERENCE TO RELATED APPLICATIONS

The disclosure claims the benefits of priority to Chinese Application No. 202111666819.8, filed on Dec. 31, 2021, which is incorporated herein by reference in its entirety.

### TECHNICAL FIELD

The present disclosure generally relates to data centers, and more particularly, to container data centers, edge data centers, and working methods.

### BACKGROUND

With the development of new-generation information technology (IT) such as the Internet, cloud computing, big data, and artificial intelligence, data centers, as the main storage and computing processing entities for massive data, are increasingly in demand. A data center is a place of IT equipment where a large number of apparatuses such as servers, storage apparatuses, and network apparatuses are gathered, and is a platform for realizing centralized processing, storage, transmission, exchange, and centralized management of data information.

A data center usually comprises a server system, a network system, an electrical system, a cooling system, a weak electricity monitoring system, a premises distribution system, a water supply and drainage system, a fire protection system, a security system, and so on, which is an integration center of complex systems. It is the direction of continuous exploration and development in the field of data centers that the data center can be delivered quickly while high operational reliability can be ensured.

### SUMMARY OF THE DISCLOSURE

Embodiments of the present disclosure provide a container data center. The data center is provided in a shipping container, and the container data center includes a cooling system including a plurality of cooling devices for cooling the data center; a power supply and distribution system including a power supply circuit for supplying power to the data center; and a control system electrically connected to the cooling system and the power supply and distribution system; wherein the control system comprises a plurality of control devices, the plurality of control devices each configured to control a part of the cooling devices, and when a first part of the plurality of control devices cannot work, a working mode of a second part of the control devices is adjusted to control the plurality of the cooling devices.

Embodiments of the present disclosure provide an edge data center. The edge data center includes an edge computing device provided inside a shipping container; a cooling system comprising a plurality of cooling devices and configured to cool the edge computing device that generates heat during working; a power supply and distribution system comprising a power supply circuit and configured to supply power to the edge data center; and a control system electrically connected to the cooling system and the power supply and distribution system; wherein the control system comprises a plurality of control devices, each of the plurality of control devices being configured to control a part of the plurality of cooling devices, and when a first part of the plurality of control devices cannot work, a working mode of a second part of the control devices is adjusted to control the plurality of cooling devices.

Embodiments of the present disclosure provide a working method for a control device in a data center, applicable to a first control device in a plurality of control devices in the data center. The method includes controlling at least one first cooling device in the data center; detecting whether at least one second control device in the plurality of control devices is working abnormally; acquiring, upon detecting a presence of a target control device that is working abnormally in the at least one second control device, an identifier of the at least one second cooling device which is controlled by the target control device; establishing a communication connection with the at least one second cooling device according to the identifier of the at least one second cooling device; and controlling the at least one second cooling device in the data center based on the established communication connection.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 is a schematic diagram of an exemplary appearance structure of a container data center, according to some embodiments of the present disclosure.

FIG. 2 is a schematic diagram of an exemplary internal structure of a container data center, according to some embodiments of the present disclosure.

FIG. 3 is a schematic diagram of an exemplary relationship of systems of a container data center, according to some embodiments of the present disclosure.

FIG. 4 is a schematic diagram illustrating principle of two control devices in a container data center, according to some embodiments of the present disclosure.

FIG. 5 is a schematic diagram of two power supply circuits, according to some embodiments of the present disclosure.

FIG. 6 is a schematic diagram illustrating a connection structure of cooling devices of a cooling system with a liquid cooling cabinet, according to some embodiments of the present disclosure.

FIG. 7 is a flowchart of an exemplary working method for a control device in a data center, according to some embodiments of the present disclosure.

FIG. 8 is a sub-flowchart of an exemplary working method for a control device in a data center, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms or definitions incorporated by reference.

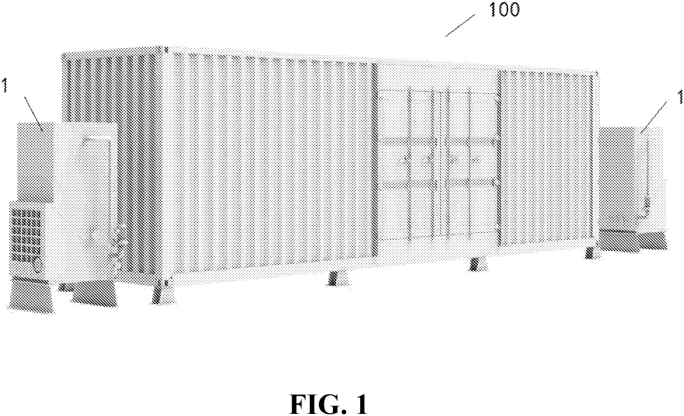

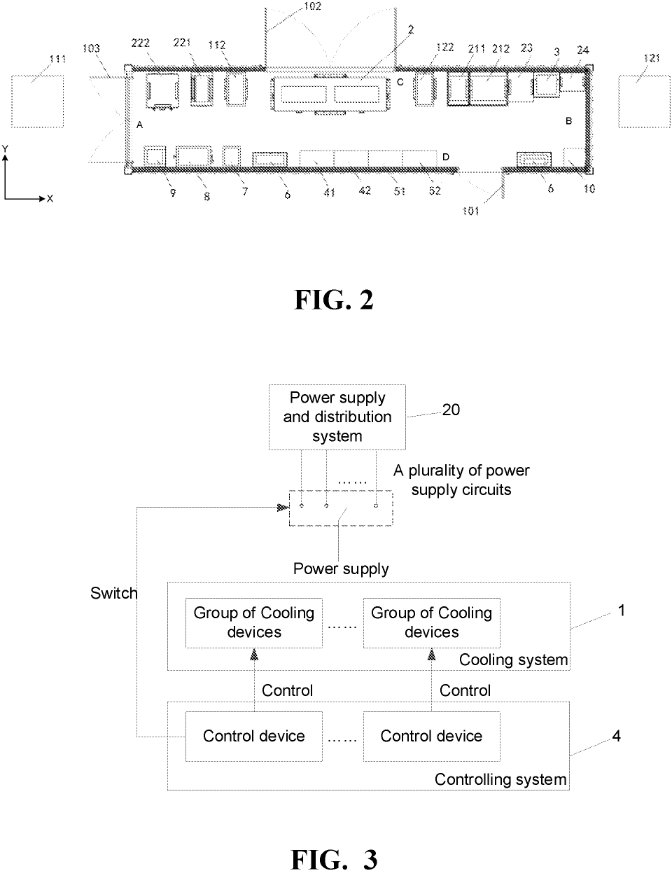

FIG. 1 illustrates a schematic diagram of an appearance structure of a container data center, according to some embodiments of the present disclosure. FIG. 2 illustrates a schematic diagram of an internal structure of a container data center, according to some embodiments of the present disclosure. FIG. 3 illustrates a schematic diagram of a relationship of systems of a container data center, according to some embodiments of the present disclosure. Specifically, referring to FIGS. 1 to 3, the container data center 100 includes a cooling system 1, a power supply and distribution system 20, and a control system 4. The cooling system 1 includes a plurality of cooling devices for cooling the data center. The power supply and distribution system 20 is provided with a power supply circuit for supplying power to the data center. The control system 4 is electrically connected to the cooling system 1 and the power supply and distribution system 20. The control system 4 includes a plurality of control devices. Each of the plurality of control devices is configured to control a part of the cooling devices. When a part of the plurality of control devices cannot work, the working mode of the remaining part of the plurality of control devices can be adjusted to control the plurality of cooling devices.

The power supply and distribution system 20 may include a plurality of power supply circuits. Accordingly, each of the plurality of control devices can be configured to control switching of the plurality of power supply circuits.

The number of the cooling devices in the cooling system 1 can be determined based on a requirement of the refrigeration for the data center in the shipping container. For example, the container data center includes a plurality of liquid cooling cabinets. In each of the liquid cooling cabinets, IT equipment (e.g., a server) is installed. In this case, two cooling devices can be configured for each of the liquid cooling cabinets.

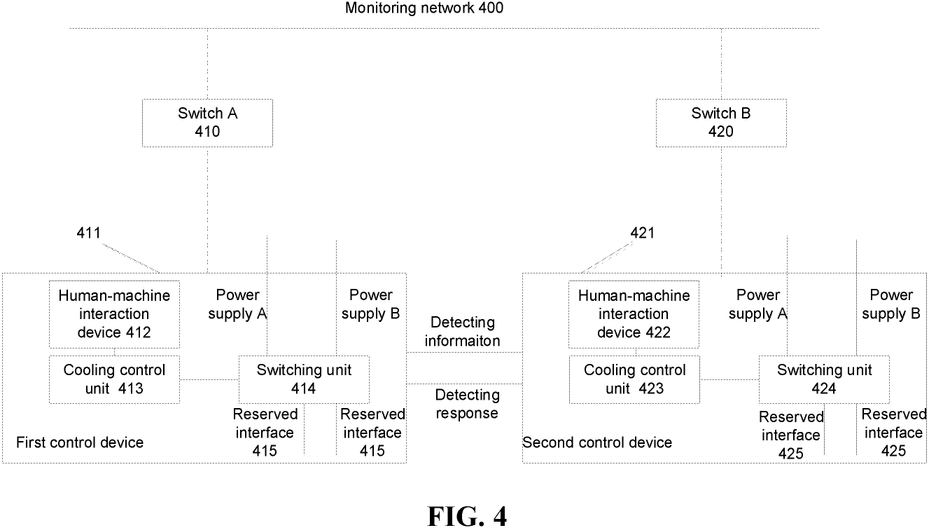

FIG. 4 is a schematic diagram illustrating principle of two control devices in a container data center, according to some embodiments of the present disclosure. As shown in FIG. 4, the control system 4 includes a first control device 411 and a second control device 421. The plurality of cooling devices are divided into two groups, namely a first group of cooling devices and a second group of cooling devices. In a cooperative mode, the first control device 411 is configured to control the first group of cooling devices and the second control device 421 is configured to control the second group of cooling devices. When the first control device 411 cannot work, the working mode of the second control device 421 can be adjusted to an independent mode. A communication connection with the first group of cooling devices can be established, and the second device 421 is configured to control the first group of cooling devices and the second group of cooling devices.

In some embodiments, the second control device 421 and the first control device 411 can detect whether the other one is working normally by sending detection information. For example, the second control device 421 is configured to send detection information to the first control device 411. If the second control device 421 receives a detection response fed back from the first control device 411 within a preset duration, the second control device 421 works in accordance with the cooperative mode. If the second control device 421 does not receive the detection response fed back from the first control device 411 within the preset duration, it is determined that the first control device 411 cannot work and the working mode of the second control device 421 is adjusted to the independent mode.

Specifically, the detection information may be heartbeat information. The first control device 411 and the second control device 421 may send detection information to each other. The example described above provides a situation where the second control device 421 sends detection information to the first control device 411. In some embodiments, the first control device 411 is configured to send the detection information and the second control device is configured to receive and respond to the detection information. In this case, the first control device 411 sends detection information to the second control device 421 and waits for a detection response from the second control device 421.

As shown in FIG. 2, a schematic diagram of the internal structure of a container data center is illustrated. In some embodiments, one control device may be provided in one control cabinet and provided with a corresponding human-machine interaction device. The control cabinet is located inside the shipping container. The human-machine interaction device is configured to display corresponding information in accordance with a control instruction from a corresponding control device and to provide an interaction interface for a user, so that the user can trigger a corresponding user instruction or export data through the interaction interface. As in the example illustrated in FIG. 2, and referring to FIG. 4, the first control device 411 may be provided in a first control cabinet 41 in FIG. 2, and the second control device 421 may be provided in a second control cabinet 42 in FIG. 2.

In some embodiments, as shown in FIG. 4, the control devices may also access to a monitoring network 400 through corresponding switches to receive, through the switches, monitoring information transmitted in the monitoring network. The control device 411, 421 may make an appropriate control decision based on the received monitoring information. Specifically, as shown in FIG. 4, the first control device 411 accesses to the monitoring network 400 through a switch A 410, and the second control device 421 accesses to the monitoring network 400 through a switch B 420.

In some embodiments, as shown in FIG. 4, the control devices 411, 421 may each includes a cooling control unit 413, 423 and a switching unit 414, 424. The cooling control units 413, 423 are electrically connected to the cooling system to control at least part of the cooling devices in the cooling system. The switching units 414, 424 are electrically connected to the plurality of power supply circuits to control switching of the plurality of power supply circuits. The switching unit 414, 424 further includes at least one reserved interface 415, 425 to facilitate expansion of a number of power supply circuits.

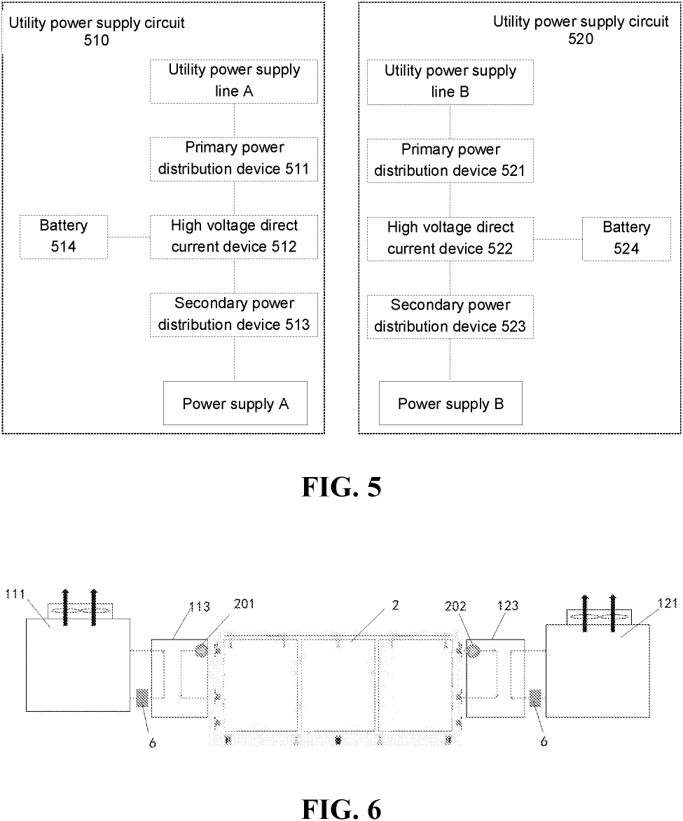

The plurality of power supply circuits in this example may include a plurality of utility power supply circuits. FIG. 5 is a schematic diagram of two power supply circuits, according to some embodiments of the present disclosure. In some embodiments, either of the utility power supply circuits may be implemented in the following structure. For example, a utility power supply circuit includes a primary power distribution device, a high voltage direct current device, a battery, and a secondary power distribution device. The primary power distribution device is used to connect to a utility power supply line via a power cable. The high voltage direct current device is electrically connected to the primary power distribution device to convert alternating current introduced into the primary power distribution device into high voltage direct current and is used as a power supply to supply power to the data center when the utility power supply is normal. The battery is electrically connected to the high voltage direct current device to be charged with an electrical energy output from the high voltage direct current device when the utility power supply is normal, and used as a power supply to supply power to the data center when the utility power supply is abnormal or interrupted. The secondary power distribution device is electrically connected to the high voltage direct current device and the battery to provide one or more power branch interfaces for different loads of the data center.

In the example as shown in FIG. 2, the primary power distribution devices of the multiple power supply circuits may be installed in a primary power distribution cabinet 24, and the secondary power distribution devices of the multiple power supply circuits may be installed in a secondary power distribution cabinet 23. For example, the two power supply circuits shown in FIG. 5 are an A-way power supply circuit 510 and a B-way power supply circuit 520, respectively. The primary power distribution cabinet 24 is provided with an A-way primary power distribution device 511 and a B-way primary power distribution device 521. The primary power distribution device 511, 512 has two outputs. Similarly, the secondary power distribution cabinet 23 is provided with an A-way secondary power distribution device 513 and a B-way secondary power distribution device 523. High voltage direct current (HVDC) devices in the power supply circuits can be installed in different high voltage direct current cabinets. As shown in FIG. 2, a high voltage direct current device 512 in FIG. 5 is provided in a first high voltage direct current cabinet 211, and a high voltage direct current device 522 in FIG. 5 is provided in a second high voltage direct current cabinet 221. Similarly, batteries configured in the power supply circuits can also be installed in different battery cabinets. For example, a battery 514 in FIG. 5 may be provided in a first battery cabinet 212 in FIG. 2, and a battery 524 may be provided in a second battery cabinet 222 in FIG. 2. In this example, the devices are installed in independent corresponding cabinets, which facilitates maintenance and repair by staff. In addition, the performance, such as isolation and heat insulation, can be improved.

The batteries may be selected from lead-acid batteries or lithium-ion batteries. The capacities of the batteries are selected according to a load of the data center, so as to at least provide power support for a preset duration when there is no external power source. For example, the battery capacities of the batteries may be configured to enable stable operation of the data center for 10 minutes, 30 minutes, 1 hour, or longer, which is not limited by the present disclosure.

In some embodiments, the primary power distribution cabinet provides a plurality of connection points for the high voltage direct current devices, and the secondary power distribution cabinet provides corresponding connection ports for different load power branches of the data center.

In addition to utility power supply circuits, the plurality of power supply circuits may also include a plurality of green-energy power supply circuits, such as solar positive power supply circuits and wind power supply circuits. Furthermore, the plurality of power supply circuits may also include diesel generators to provide power supply circuits, etc.

The arrangement of these devices and cabinets in the shipping container also requires to be designed. Assuming that the container data center includes two power supply circuits. The two batteries in these two power supply circuits are installed in two battery cabinets, respectively. The two battery cabinets can be deployed at different locations of the shipping container in a scattered manner. Since batteries may generate heat during charging and discharging, arranging the two battery cabinets together may lead to high local temperature in the shipping container. The battery cabinets being scattered is conducive to the heat dissipation of the battery cabinets. For example, in the example illustrated in FIG. 2, the first battery cabinet 212 and the second battery cabinet 222 are located at the two ends of the shipping container along a direction of the length of the shipping container (e.g., an X direction). In addition, control cabinets and electric control cabinets in which control devices including electronic equipment (e.g., instruments) are installed can be provided on the side away from the heat source. For example, in FIG. 2, in a direction of the width of the shipping container (e.g., a Y direction), the liquid cooling cabinets 2 in which the IT equipment of the data center is installed are provided on one side of the shipping container, and the first control cabinet 41 and the second control cabinet 42 as well as the first electric control cabinet 51 and the second electric control cabinet 52 may be provided on the other side of the shipping container.

FIG. 2 illustrates a schematic diagram of an exemplary internal structure of a container data center, according to some embodiments of the present disclosure. As shown in FIG. 2, the shipping container may be provided with a plurality of dedicated doors, such as a first door 101 dedicated to staff access, a second door 102 dedicated to access or maintenance of the liquid cooling cabinet 2, and a third door 103 toward the external cooling assembly 111 of the cooling device, and the like. The interior space of the shipping container includes two ends along the direction of length (e.g., an X direction), namely a first end A (corresponding to a left end in FIG. 2) and a second end B (corresponding to a right end in FIG. 2). The interior space of the shipping container includes two sides along the direction of width (e.g., a Y direction), namely a first side C (corresponding to an upper side in FIG. 2) and a second side D (corresponding to a lower side in FIG. 2). From the first end A to the second end B, the first side C of the shipping container is provided with, in sequence: the second battery cabinet 222, the second high voltage direct current cabinet 221, a second coolant distribution unit 112, the liquid cooling cabinet 2, a first coolant distribution unit 122, the first high voltage direct current cabinet 211, the first battery cabinet 212, the secondary power distribution cabinet 23, a power monitoring cabinet 3, and the primary power distribution cabinet 24. From the first end A to the second end B, the second side D of the shipping container is provided with, in sequence: a purification device 9, a replenishment device 8, a replenishment pump 7, a hydraulic device 6, the first control cabinet 41, the second control cabinet 42, the first electric control cabinet 51, the second electric control cabinet 52, another hydraulic device 6, a fire protection device 10, and so on.

The electric power monitoring cabinet 3 in this example may be provided with a variety of monitoring devices, apparatuses, etc., which can be used for acquisition of data such as the voltage, current, frequency, power, and temperature, a switch quantity (such as the switch position and valve position), an event signal (such as a position change of the status of the switch, etc.), an advance warning signal, an over-temperature tripping signal, etc. The instruments and devices in the first electric control cabinet 51 and the second electric control cabinet 52 are the same and have the same functions. The first electric control cabinet 51 and the second electric control cabinet 52 are used as a backup for each other, so that in case of failure of one of the electric control cabinets, the other electric control cabinet can take over the work of the two electric control cabinets. It should be noted here that the specific implementation structures of the electric control cabinet, the power monitoring cabinet, the primary power distribution cabinet, the secondary power distribution cabinet, the high voltage direct current cabinet, etc., are not specifically limited in the present disclosure, and can be determined according to the actual needs of the data center, or can be implemented with reference to what is documented in the relevant literature.

Since chilled-water cooling devices consume less energy than air- or water-cooling equipment, the data center can use chilled-water cooling devices for temperature regulation, and in order to control chilled water delivered to the cooling devices, the chilled water is usually transferred to the external cooling assemblies of the cooling devices through a coolant distribution unit (CDU) to achieve on-demand distribution of the chilled water. The source of the chilled water can be tap water, lake water or well water in the area where that data center is located, etc., which is not limited in the present disclosure. That is, the cooling devices in this example can be implemented with the following structure. Specifically, the cooling devices each includes a heat exchange assembly and an external cooling assembly. The heat exchange assembly is provided inside the shipping container and the external cooling assembly is provided outside the shipping container. The heat exchange assembly includes a heat exchanger and a coolant distribution unit. The heat exchanger is used to absorb heat generated during working of IT equipment of the data center. The coolant distribution unit is in fluid communication with the heat exchanger and the external cooling assembly to form a coolant circulation pipeline for regulating the flow volume and flow rate of coolant in the coolant circulation pipeline. The coolant distribution unit implements a constant-temperature and constant-pressure control strategy by keeping the temperature and pressure of the external cooling water supply stable, so as to prevent the temperature of the coolant from getting too low, and also to save energy at low thermal loads and improve the power usage effectiveness (PUE) of the data center. For example, when the thermal load is low, the flow volume or flow rate of the coolant in the coolant circulation pipeline is reduced, thus saving electrical energy.

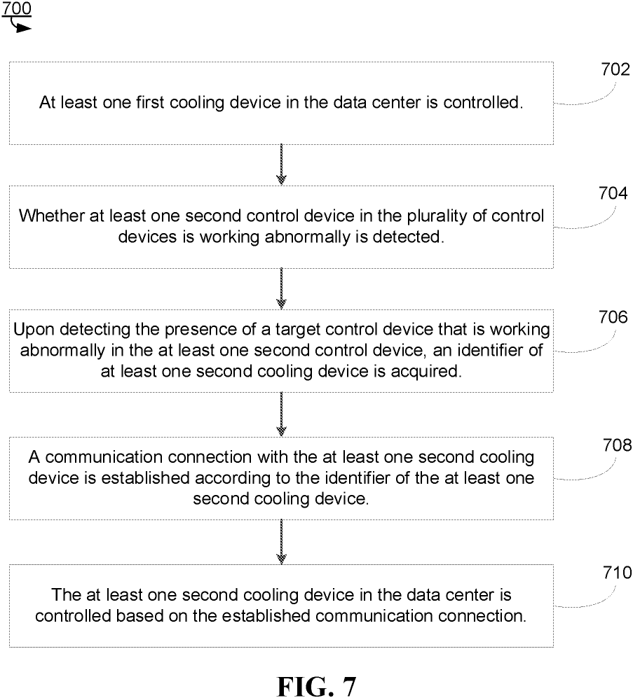

FIG. 6 is a schematic diagram illustrating a connection of cooling devices of a cooling system with a liquid cooling cabinet, according to some embodiments of the present disclosure. As illustrated in FIG. 6, the container data center includes two cooling devices. One of the cooling devices includes a first heat exchange assembly 113 and a first external cooling assembly 111. The other cooling device includes a second heat exchange assembly 123 and a second external cooling assembly 121. The first heat exchange assembly 113 includes a first heat exchanger and a first coolant distribution unit 122 (as shown in FIG. 2), and the second heat exchange assembly 123 includes a second heat exchanger and a second coolant distribution unit 112 (as shown in FIG. 2).

The external cooling assembly may include an evaporative condensation assembly and a power assembly. The evaporative condensation assembly dissipates, in an evaporative cooling manner, the heat absorbed by the heat exchanger, and the power assembly provides refrigeration power for the evaporative condensation assembly. The evaporative condensation assembly may include: a condenser, a spraying device, a ventilation device, etc. The condenser is connected to the power assembly. The spraying device is used to spray heat dissipation liquid to the condenser. The ventilation device is used to provide heat dissipation airflow to the condenser. The external cooling assembly further includes a water collecting tray and a heating device. The water collecting tray is located below the condenser for collecting the heat dissipation liquid sprayed by the spraying device. The heating device is used to start heating when the temperature of liquid in the water collecting tray is lower than a threshold.

The power assembly may include a compressor and a pump. The compressor and pump are used to circulate fluid through the coolant circulation pipeline. The compressor and the pump can work separately, i.e., one works and the other shuts off. In some embodiments, the compressor and the pump can also work simultaneously. When working simultaneously, the compressor can work in a frequency conversion manner.

As shown in FIG. 6 and FIG. 2, the cooling device provided in this example may further include a hydraulic device 6. The hydraulic device 6 is provided inside the shipping container. The hydraulic device 6 is used to replenish coolant into the coolant circulation pipeline after receiving a control instruction from the control system.

In some embodiments, the container data center as described in FIG. 2 and FIG. 6 further includes a liquid cooling cabinet 2. Insulating immersion liquid is provided inside the liquid cooling cabinet 2, and the plurality of servers are immersed in the immersion liquid. An immersion liquid circulation device is provided on the liquid cooling cabinet 2 to enable the immersion liquid inside the liquid cooling cabinet to circulate and flow and exchange heat with the heat exchanger, so as to cool the IT equipment (e.g., the servers) of the data center. As shown in FIG. 6, the immersion liquid circulation device on the liquid cooling cabinet 2 may be a circulation pump, and there may be two circulation pumps, namely, a first circulation pump 201 and a second circulation pump 202. The first circulation pump 201 is provided on a first pipeline and the second circulation pump 202 is provided on a second pipeline. The first pipeline is located inside the first heat exchange assembly 113 to exchange heat with the heat exchanger of the first heat exchange assembly 113. The second pipeline is located inside the second heat exchange assembly 123 to exchange heat with the heat exchanger of the second heat exchange assembly 123.

In some embodiments, the container data center provided in the present disclosure may further include the purification device 9 and the replenishment device 8 which are provided inside the shipping container. In a specific implementation, the replenishment device 8 may also be configured with a corresponding replenishment pump 7. The purification device 9 and the replenishment device 8 are both electrically connected to the control system. When the amount or cleanliness of the immersion liquid in the liquid cooling cabinet 2 is determined not to meet requirements, the control system is further configured to control the purification device 9 to purify the immersion liquid, or to control the replenishment device to replenish an appropriate amount of immersion liquid into the liquid cooling cabinet 2. For example, an amount of immersion liquid is added to meet the requirement. In some embodiments, the control system can determine, based on a conductivity monitoring signal for the immersion liquid, whether the immersion liquid in the liquid cooling cabinet 2 needs to be purified; and can determine, based on a liquid level monitoring signal for the immersion liquid, whether an appropriate amount of immersion liquid needs to be replenished to the liquid cooling cabinet 2.

In some embodiments, the control device in the control system in this example can receive the following information for making corresponding control decisions: a water supply temperature and a return water temperature of the coolant distribution unit; an outlet water temperature of the external cooling assembly, an inlet temperature of the coolant circulation pump, and an outlet pressure, etc.; a liquid level of the immersion liquid in the liquid cooling cabinet, a conductivity of the immersion liquid, a PH value of the immersion liquid, etc.; an operation status of the external cooling assembly, a fault signal of the external cooling assembly, a manual or automatic switching instruction for the external cooling assembly, a start/stop instruction for the external cooling assembly, a frequency conversion signal for the external cooling assembly, an operation parameter (such as the opening degree of each switch valve) fed back during the operation of the external cooling assembly, etc.; an operation status of the coolant circulation pump in the cooling device, a fault signal for the coolant circulation pump, a manual or automatic switching instruction for the coolant circulation pump, a start/stop instruction for the coolant circulation pump, etc.; control information and opening degree of an electric regulating valve in the CDU; a liquid level in a water replenishing tank corresponding to the spraying device, a liquid level in the water collecting tray, etc.; a conductivity and PH value of the coolant in the CDU, etc.; a heating status of and a start instruction for the water collecting tray heating device; an operation status of a replenishment pump, manual or automatic switching of the replenishment pump, a fault signal of the replenishment pump, a start/stop status of the replenishment pump, etc.; a start/stop signal for fan coils in the external cooling assembly; supply and return liquid flow volumes of the liquid cooling cabinet, a temperature of high-level liquid, and a temperature of low-level liquid in the liquid cooling cabinet; and an operation status, a fault signal, manual or automatic switching, a start/stop status of the circulation pump of the liquid cooling cabinet, etc.

The container data center means that a data center is disposed in a shipping container and is equipped with network and power source around the shipping container. The container data center has the characteristics of high density, low PUE, rapid deployment, and one-stop service. Hot and cold channels inside the shipping container are separated and fully enclosed, which reduces the power consumed by the cold air. Rapid deployment means that container data centers do not require enterprises to invest in land, server room construction, and hardware equipment, which saves the time required for enterprises to build data centers.

The container data center adopts an integrated system design, considering various factors, and is already assembled and functionally tested before leaving the factory, so that only some simple installation and functional verification are required at the engineering site before in to service. Thus, the container data center can achieve Full Stack Delivery.

In addition, the IT equipment (such as servers, etc.) in the data center of the present disclosure is cooled using single-phase immersion liquid. Electronic equipment such as servers is completely immersed in the tank of the liquid cooling cabinet that houses the insulating coolant. The immersion liquid only warms up (without undergoing a phase change) after absorbing heat from the IT equipment, exchanges heat with the heat exchanger of the cooling system through the liquid circulation system, and then transfers the heat to the outside environment through the external cooling assembly. The cooling system in the present disclosure can be implemented by a green and environmentally friendly system. For example, the external cooling assembly in the present disclosure may include an evaporative condensation assembly to perform cooling by means of evaporative condensation. Specifically, in summer, water can be sprayed on the condenser in the evaporative condensation assembly to speed up cooling. In winter, only natural cold air is needed to cool down the condenser in the evaporative condensation assembly.

Some embodiments of the present disclosure provide an edge data center.

In an edge computing mode, to better support high-density, high-bandwidth, and low-latency scenarios, the only effective way is to build a service platform on the edge side of the network close to users, which can provide storage, computing, network and other resources, to sink some key services to the edge of the access network, so as to reduce the bandwidth and latency loss caused by network transmission and multi-level forwarding. Therefore, the Edge Data Center (also called Edge Internet Data Center) appears. It is no longer necessary to upload massive amounts of data to the cloud for processing, thus greatly reducing network latency. At the same time, the transmission pressure on the core network decreases, which avoids network congestion and makes the network transmission rate increase greatly.

Edge data centers are deployed very close to information sources and are extremely widely distributed due to their territorial (below prefecture-level city) deployment characteristics, thus meeting only the needs of local users and having characteristics of small scale, large quantity, and scattered deployment. Therefore, there is a need to propose a secure and reliable solution that can be deployed quickly.

An edge data center provided by the present disclosure may have a structure similar to the container data center provided by the above embodiments. In some embodiments, the edge data center includes, an edge computing device, a cooling system, a power supply and distribution system, and a control system. The edge computing device is provided inside a shipping container. The cooling system includes a plurality of cooling devices for cooling the edge computing device that generates heat during working. The power supply and distribution system include a plurality of power supply circuits for supplying power to the edge data center. The control system is electrically connected to the cooling system and the power supply and distribution system. The control system includes a plurality of control devices. Each of the plurality of control devices is configured to control switching of the plurality of power supply circuits. Each of the plurality of control devices is configured to control a part of the cooling devices. When a part of the multiple control devices cannot work, the working mode of the remaining part of the control devices is capable is adjusted and the remaining part of the control devices is configured to the plurality of cooling devices.

The edge computing device in the present disclosure may also be cooled in a single-phase immersion liquid cooling manner. That is, the edge computing device is provided in a liquid cooling cabinet 2 as shown in FIG. 2. The liquid cooling cabinet accommodates insulating immersion liquid that absorbs the heat generated by the edge computing device and the heat is transferred to the external environment through the heat exchange assembly and the external cooling assembly in the cooling device.

In some embodiments, the control system includes a first control device and a second control device. The plurality of cooling devices are divided into two groups, namely a first group of cooling devices and a second group of cooling devices. In a cooperative mode, the first control device is configured to control the first group of cooling devices and the second control device is configured to control the second part of cooling devices. When the first control device cannot work, the working mode of the second control device is adjusted to an independent mode, and a communication connection with the first part of cooling devices is established. The second control device is configured to control the first group of cooling devices and the second group of cooling devices.

In some embodiments, the cooling devices each includes a heat exchange assembly and an external cooling assembly. The heat exchange assembly is provided inside the shipping container and the external cooling assembly is provided outside the shipping container. The heat exchange assembly includes a heat exchanger and a coolant distribution unit. The heat exchanger is used to absorb heat generated during working of the edge computing device. The coolant distribution unit is in fluid communication with the heat exchanger and the external cooling assembly to form a coolant circulation pipeline for regulating a flow volume, a flow rate, and cleanliness of coolant in the coolant circulation pipeline. The external cooling assembly includes an evaporative condensation assembly and a power assembly. The evaporative condensation assembly dissipates, in an evaporative cooling manner, the heat absorbed by the heat exchanger, and the power assembly provides refrigeration power for the evaporative condensation assembly.

In some embodiments, the evaporative condensation assembly includes a condenser, a spraying device, and a ventilation device. The condenser is connected to the power assembly. The spraying device is used to spray heat dissipation liquid to the condenser. The ventilation device is used to provide heat dissipation airflow to the condenser. The external cooling assembly further comprises a water collecting tray and a heating device. The water collecting tray is located below the condenser for collecting the heat dissipation liquid sprayed by the spraying device. The heating device is used to start heating when the temperature of liquid in the water collecting tray is lower than a threshold.

Edge hardware mainly refers to a range of infrastructure such as edge general purpose servers, network apparatuses, refrigeration, etc. The deployment location of edge computing is often closer to users, so the deployment space is smaller compared to traditional data centers, the condition of server rooms is poorer compared to traditional data centers, and the deployment scale dynamically and flexibly scales up and down according to user needs, all of which put forward more new requirements for edge hardware, including but not limited to: high-density computing and storage capabilities, the capability of operation and maintenance in a smaller space, higher reliability (stable operation capability to adapt to harsh environments), self-heat dissipation capability, etc.

It needs to be noted here that the implementation structure of the edge data center and the control logic of the control system provided in this example may be the same as those of the container data center described above. Structures not detailed in this embodiment can be found above and will not be repeated here.

Based on the above embodiments of various types of data centers, the present disclosure also provides a working method for a control device in a data center. FIG. 7 is a flowchart of an exemplary working method 700 for a control device in a data center, according to some embodiments of the present disclosure. The method 700 can be executed by any of the plurality of control devices in the data center. Hereinafter, for ease of description, in this example, the method 700 is performed by the first control device. Specifically, the method 700 includes steps 702 to 710.

At step 702, at least one first cooling device in the data center is controlled.

At step 704, whether at least one second control device in the plurality of control devices is working abnormally is detected.

At step 706, upon detecting the presence of a target control device that is working abnormally in the at least one second control device, an identifier of at least one second cooling device is acquired. The at least one second cooling device is controlled by the target control device.

At step 708, a communication connection with the at least one second cooling device is established according to the identifier of the at least one second cooling device.

At step 710, the at least one second cooling device in the data center is controlled based on the established communication connection.

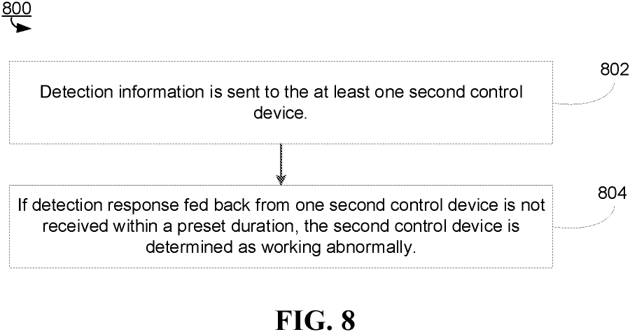

FIG. 8 is a sub-flowchart of an exemplary working method 800 for a control device in a data center, according to some embodiments of the present disclosure. In some embodiments, step 704 of FIG. 7 for detecting the presence of a target control device that is working abnormally in the at least one second control device, an identifier of at least one second cooling device is acquired, further includes steps 802 and 804:

At step 802, detection information is sent to the at least one second control device.

At step 804, if detection response fed back from one second control device is not received within a preset duration, the second control device is determined as working abnormally.

In some embodiments of the present disclosure, such as the container data center, the edge data center, etc., the control devices in the data center can implement the functions corresponding to the above steps.

The technical solutions provided in the embodiments of the present application, i.e., the cooling system, the power supply and distribution system, and the control system are all designed with high reliability and can meet the requirements of the medium data reliability Tier III, i.e., the criteria of “on-line maintenance”. The criteria of on-line maintenance are that: the equipment and distribution paths are all redundant, and any component of the system can be replaced or maintained without affecting the operation of the system. In addition, to reduce the PUE, the data center in this embodiment can cool down the electronic equipment such as servers and switches in a single-phase immersion liquid cooling manner. The cooling source in the cooling system may be a non-compression cooling source, which can realize natural cooling throughout the year. The approach that the single-phase immersion liquid cooling together with a natural cooling system can significantly reduce the PUE of the data center, thus efficiently solving the heat dissipation of servers.

In some embodiments, a non-transitory computer-readable storage medium including instructions is also provided, and the instructions may be executed by a device, for performing the above-described methods. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same. The device may include one or more processors (CPUs), an input/output interface, a network interface, or a memory.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

It is appreciated that the above-described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. One of ordinary skill in the art will also understand that multiple ones of the above-described modules/units may be combined as one module/unit, and each of the above-described modules/units may be further divided into a plurality of sub-modules/sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A container data center having a data center provided in a shipping container, the container data center comprises:
a cooling system comprising a plurality of cooling devices for cooling the data center;
a power supply and distribution system comprising a power supply circuit for supplying power to the data center; and
a control system electrically connected to the cooling system and the power supply and distribution system,
wherein the control system comprises a plurality of control devices, the plurality of control devices each configured to control a part of the cooling devices, and when a first part of the plurality of control devices cannot work, a working mode of a second part of the control devices is adjusted to control the plurality of the cooling devices.

2. The container data center according to claim 1, wherein the control system comprises a first control device and a second control device;
the plurality of cooling devices comprises a first group of cooling devices and a second group of cooling devices, wherein
in a cooperative mode, the first control device is configured to control the first group of cooling devices and the second control device is configured to control the second group of cooling devices; and
when the first control device cannot work, a work mode of the second control device is adjusted to an independent mode, and a communication connection with the first group of cooling devices is established and the second control device is configured to control the first group of cooling devices and the second group of cooling devices.

3. The container data center according to claim 2, wherein
the second control device is configured to send detection information to the first control device,
when a detection response fed back from the first control device is received within a preset duration, the second control device is configured to work in accordance with the cooperative mode; and
when a detection response fed back from the first control device is not received within the preset duration, the first control device is determined as working abnormally and the work mode of the second control device is adjusted to the independent mode.

4. The container data center according to claim 2, wherein one control device is provided in one control cabinet and is configured with a corresponding human-machine interaction device; wherein
the control cabinet is located inside the shipping container;
the human-machine interaction device is configured to display corresponding information in accordance with a control instruction from a corresponding control device and to provide an interaction interface for a user, wherein the user can trigger a corresponding user instruction or export data through the interaction interface;
the power supply and distribution system comprises a plurality of power supply circuits, wherein each of the plurality of control devices is configured to control switching of the plurality of power supply circuits; and
the control device comprises:
a cooling control unit electrically connected to the cooling system and configured to control at least part of the cooling devices in the cooling system, and
a switching unit electrically connected to the plurality of power supply circuits and configured to control switching of the plurality of power supply circuits, wherein the switching unit further comprises at least one reserved interface configured to facilitate expansion of a number of power supply circuits.

5. The container data center according to claim 1, wherein the power supply and distribution system comprises a plurality of power supply circuits comprising a plurality of utility power supply circuits, wherein each of the plurality of utility power supply circuits comprises:
a primary power distribution device configured to connect to a utility power supply line via a power cable;
a high voltage direct current device electrically connected to the primary power distribution device and configured to convert an alternating current introduced into the primary power distribution device into a high voltage direct current, and when a utility power supply is normal, the high voltage direct current device is used as a power supply to supply power to the data center;
a battery electrically connected to the high voltage direct current device, wherein when the utility power supply is normal, the battery is configured to be charged with an electrical energy output from the high voltage direct current device; when the utility power supply is abnormal or interrupted, the battery is used as a power supply to supply power to the data center; and
a secondary power distribution device electrically connected to the high voltage direct current device and the battery, and configured to provide one or more power branch interfaces for different loads of the data center.

6. The container data center according to claim 1, wherein each of the plurality of cooling devices comprises:
a heat exchange assembly provided inside the shipping container; and
an external cooling assembly provided outside the shipping container;
wherein the heat exchange assembly comprises:
a heat exchanger configured to absorb heat generated during working of IT equipment of the data center; and
a coolant distribution unit in fluid communication with the heat exchanger and the external cooling assembly, and configured to form a coolant circulation pipeline for regulating a flow volume and a flow rate of coolant in the coolant circulation pipeline.

7. The container data center according to claim 6, wherein the external cooling assembly comprises:
an evaporative condensation assembly configured to dissipate, in an evaporative cooling manner, the heat absorbed by the heat exchanger; and
a power assembly configured to provide refrigeration power for the evaporative condensation assembly.

8. The container data center according to claim 7, wherein the evaporative condensation assembly comprises:
a condenser connected to the power assembly;
a spraying device configured to spray heat dissipation liquid to the condenser; and
a ventilation device configured to provide heat dissipation airflow to the condenser; wherein
the external cooling assembly further comprises:
a water collecting tray located below the condenser and configured to collect the heat dissipation liquid sprayed by the spraying device; and
a heating device configured to start heating when a temperature of liquid in the water collecting tray is lower than a threshold.

9. The container data center according to claim 6, further comprising:
a liquid cooling cabinet containing insulating immersion liquid, wherein a plurality of servers are immersed in the immersion liquid; and
an immersion liquid circulation device provided on the liquid cooling cabinet and configured to enable the immersion liquid inside the liquid cooling cabinet to circulating flow and exchange heat with the heat exchanger to cool the IT equipment of the data center.

10. The container data center according to claim 9, further comprising a purification device and a replenishment device, both the purification device and the replenishment device being provided inside the shipping container and electrically connected to the control system; wherein
when an amount or cleanliness of the immersion liquid in the liquid cooling cabinet is determined to not meet requirements, the control system is further configured to control the purification device to purify the immersion liquid, or to control the replenishment device to replenish an amount of immersion liquid into the liquid cooling cabinet.

11. An edge data center, comprising:
an edge computing device provided inside a shipping container;
a cooling system comprising a plurality of cooling devices and configured to cool the edge computing device that generates heat during working;
a power supply and distribution system comprising a power supply circuit and configured to supply power to the edge data center; and
a control system electrically connected to the cooling system and the power supply and distribution system; wherein the control system comprises a plurality of control devices, each of the plurality of control devices being configured to control a part of the plurality of cooling devices, and when a first part of the plurality of control devices cannot work, a working mode of a second part of the control devices is adjusted to control the plurality of cooling devices.

12. The edge data center according to claim 11, wherein the control system comprises a first control device and a second control device; and
the plurality of cooling devices comprise a first group of cooling devices and a second group of cooling devices, wherein
in a cooperative mode, the first control device is configured to control the first group of cooling devices and the second control device is configured to control the second group of cooling devices; and
when the first control device cannot work, a working mode of the second control device is adjusted to an independent mode, and a communication connection with the first group of cooling devices is established and the second control device is configured to control the first group of cooling devices and the second group of cooling devices.

13. The edge data center according to claim 10, wherein each of the plurality of cooling devices comprises:
a heat exchange assembly provided inside the shipping container; and
an external cooling assembly provided outside the shipping container; wherein
the heat exchange assembly comprises:
a heat exchanger configured to absorb heat generated during working of the edge computing device; and
a coolant distribution unit in fluid communication with the heat exchanger and the external cooling assembly, and configured to form a coolant circulation pipeline for regulating a flow volume, a flow rate, and cleanliness of coolant in the coolant circulation pipeline; and
the external cooling assembly comprises:
an evaporative condensation assembly configured to dissipate, in an evaporative cooling manner, the heat absorbed by the heat exchanger; and
a power assembly configured to provide refrigeration power for the evaporative condensation assembly.

14. The edge data center according to claim 13, wherein the evaporative condensation assembly comprises:
a condenser connected to the power assembly;
a spraying device configured to spray heat dissipation liquid to the condenser; and
a ventilation device configured to provide heat dissipation airflow to the condenser; wherein
the external cooling assembly further comprises:
a water collecting tray located below the condenser and configured to collect the heat dissipation liquid sprayed by the spraying device; and
a heating device configured to start heating when a temperature of liquid in the water collecting tray is lower than a threshold.

15. The edge data center according to claim 13, further comprising:
a liquid cooling cabinet containing insulating immersion liquid, wherein the edge computing device is immersed in the immersion liquid; and
an immersion liquid circulation device provided on the liquid cooling cabinet and configured to enable the immersion liquid inside the liquid cooling cabinet to circulate flow and exchange heat with the heat exchanger to cool the edge computing device.

16. The edge data center according to claim 15, further comprising a purification device and a replenishment device, both the purification device and the replenishment device being provided inside the shipping container and electrically connected to the control system; wherein
when an amount or cleanliness of the immersion liquid in the liquid cooling cabinet is determined to not meet requirements, the control system is further configured to control the purification device to purify the immersion liquid, or to control the replenishment device to replenish an amount of immersion liquid into the liquid cooling cabinet.

17. The edge data center according to claim 12, wherein
the second control device is configured to send detection information to the first control device,
when a detection response fed back from the first control device is received within a preset duration, the second control device is configured to work in accordance with the cooperative mode; and
when a detection response fed back from the first control device is not received within the preset duration, the first control device is determined as working abnormal and the work mode of the second control device is adjusted to the independent mode.

18. The edge data center according to claim 12, wherein one control device is provided in one control cabinet and is configured with a corresponding human-machine interaction device; wherein
the control cabinet is located inside the shipping container;
the human-machine interaction device is configured to display corresponding information in accordance with a control instruction from a corresponding control device and to provide an interaction interface for a user, wherein the user can trigger a corresponding user instruction or export data through the interaction interface;
the power supply and distribution system comprises a plurality of power supply circuits, wherein each of the plurality of control devices is configured to control switching of the plurality of power supply circuits;
the control device comprises:
a cooling control unit electrically connected to the cooling system and configured to control at least part of the cooling devices in the cooling system, and
a switching unit electrically connected to the plurality of power supply circuits and configured to control switching of the plurality of power supply circuits, wherein the switching unit further comprises at least one reserved interface configured to facilitate expansion of a number of power supply circuits.

19. A working method for a control device in a data center, applicable to a first control device in a plurality of control devices in the data center, comprising:
controlling at least one first cooling device in the data center;
detecting whether at least one second control device in the plurality of control devices is working abnormally;
acquiring, upon detecting a presence of a target control device that is working abnormally in the at least one second control device, an identifier of the at least one second cooling device that is controlled by the target control device;
establishing a communication connection with the at least one second cooling device according to the identifier of the at least one second cooling device; and
controlling the at least one second cooling device in the data center based on the established communication connection.

20. The method according to claim 19, wherein detecting whether at least one second control device in the plurality of control devices is working abnormally comprises:
sending detection information to the at least one second control device; and
determining, when a detection response fed back from the second control device is not received within a preset duration, the second control device being working abnormally.
